(19) United States
(12) Patent Application Publication
(10) Pub. No.: US 2008/0176403 A1
(43) Pub. Date: Jul. 24, 2008

(54) Method of polishing a layer and method of manufacturing a semiconductor device using the same

(75) Inventors: Jun-Yong Kim, Gyeonggi-do (KR); Chang-Ki Hong, Gyeonggi-do (KR); Bo-Un Yoon, Seoul (KR); Byoung-Ho Kwon, Gyeonggi-do (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 11/983,281

(22) Filed: Nov. 8, 2007

(30) Foreign Application Priority Data
Nov. 16, 2006 (KR) 10-2006-0113083

(51) Int. Cl. H01L 21/306; C23F 1/00

(52) U.S. Cl. 438/697; 216/38; 257/E21.219

(57) ABSTRACT

In a method of chemically and mechanically polishing a layer, a substrate on which the layer having stepped portions is formed is prepared. The layer is primarily chemically and mechanically polished at a temperature of about 30° C. to about 80° C. to remove the stepped portions of the layer. The layer is secondarily chemically and mechanically polished without the stepped portions at a temperature of about 5° C. to about 25° C. to form a flat layer having a desired thickness. Thus, the stepped portions may be rapidly removed in an initial period so that the method may have an improved throughput.

### CROSS-REFERENCE TO RELATED APPLICATION

This application claims priority under 35 USC §119 to Korean Patent Application No. 10-2006-0113083, filed in the Korean Intellectual Property Office on Nov. 16, 2006, the contents of which are herein incorporated by reference in their entirety for all purposes.

### BACKGROUND OF THE INVENTION

1. Field of the Invention

Example embodiments of the present invention relate to a method of polishing a layer and a method of manufacturing a semiconductor device using the same. More particularly, example embodiments of the present invention relate to a method of chemically and mechanically polishing a layer to ensure a high planarity thereof and a method of manufacturing a semiconductor device using the same.

2. Description of the Related Art

Generally, processes for manufacturing a semiconductor memory device may include forming a structure having a flat surface. The structure of the semiconductor memory device may be formed by a deposition process, a patterning process, an etching process, a polishing process, etc. The polishing process may usually include a chemical mechanical polishing (CMP) process that is widely used for polishing a semiconductor substrate.

The CMP process may include holding the semiconductor substrate, providing a slurry composition including an abrasive between the semiconductor substrate and a polishing pad, and rotating the semiconductor substrate, which makes contact with the polishing pad, to planarize the surface of the semiconductor substrate by pressurization and rotation. In the CMP process, the surface of the semiconductor substrate is rubbed against the abrasive and surface protrusions of the polishing pad to mechanically polish the surface of the semiconductor substrate and is simultaneously chemically reacted with chemical components in the slurry composition to chemically remove the surface of the semiconductor substrate.

The polishing efficiency of the CMP process is affected by the CMP apparatus being used, the composition ratio of the slurry composition, the type of polishing pad, etc. Specifically, the composition ratio of the slurry composition may have an important effect on the polishing efficiency of the CMP process.

Polishing speeds with respect to layers using a slurry composition having a composition ratio substantially the same may be different from each other depending on properties of the layers. Thus, the polished thicknesses of the layers may be controlled using the difference between the polishing speeds. Specifically, the CMP process may be performed on an oxide layer, a nitride layer, a polysilicon layer and a metal layer of the semiconductor device between which polishing speeds exist.

Recently, to improve planarity of a silicon oxide layer having a high step, a CMP process having high planarity has been developed. The CMP process having the high planarity uses a high-planarity slurry composition including a passivation agent, i.e., an ionic surfactant.

According to a conventional method of chemically and mechanically polishing a layer having high planarity, the ionic surfactant in the high planarity slurry composition is electrically absorbed on a surface of the silicon oxide layer to form a polishing stop layer. The polishing stop layer suppresses a chemical polishing reaction. Therefore, the silicon oxide layer may be polished mainly by the mechanical polishing process.

As a result, when stepped portions on the silicon oxide layer are mechanically removed, the polished area of the silicon oxide layer on which the polishing stop layer making contact with a polishing pad is formed is widened so that polishing pressure applied to the silicon oxide layer is distributed. The distribution of the polishing pressure may greatly reduce the polishing rate of the silicon oxide layer to provide the silicon oxide layer with a self-stopping characteristic, thereby obtaining a high-planarized surface of the silicon oxide layer.

However, the conventional CMP method having high planarity may require a very long polishing time; about 4 times to about 5 times longer than that of a generally used CMP method. This may cause use restriction of the conventional CMP method having the high planarity. Particularly, when the conventional CMP method having the high planarity is carried on the stepped portions of the silicon oxide layer using a ceria slurry composition, a removal rate of the silicon oxide layer during an initial period of the conventional CMP method may be very low so that a loading effect, a phenomenon in which excessive polishing time is exhausted, may be generated. After a lapse in the predetermined time, the removal rate of the silicon oxide layer may be markedly increased so that the silicon oxide layer is actually removed.

Therefore, since a process time of the conventional CMP process having the high planarity may be too long, the conventional CMP process having the high planarity may have a low throughput. Thus, developments of a CMP process having high planarity, which has good characteristics of the above-mentioned CMP process having the high planarity and a rapid speed with respect to the silicon oxide layer, have recently been required. However, improvements of the CMP process having the high planarity may not be properly ensured.

### SUMMARY OF THE INVENTION

Example embodiments of the present invention provide a method of polishing a layer having high planarity that is capable of improving a polishing speed of stepped portions of the layer by two controls.

Example embodiments of the present invention also provide a method of manufacturing a semiconductor device using the above-mentioned method.

According to one aspect, the present invention is directed to a method of polishing a layer. According to the method, a substrate on which the layer having stepped portions is formed is prepared. The layer is primarily chemically and mechanically polished at a temperature of about 30° C. to about 80° C. to remove the stepped portions of the layer. The layer is secondarily chemically and mechanically polished without the stepped portions at a temperature of about 5° C. to about 25° C. to form a layer pattern having a desired thickness.

According to example embodiments, the primarily and the secondarily chemically and mechanically polishing the layer may be performed using about 0.5% to about 10% by weight of a cerium oxide abrasive, about 0.1% to about 3.0% by weight of a surfactant, and remaining water. The layer may include silicon oxide. The silicon oxide layer has the stepped portions through formation of the silicon oxide layer on structures that are formed on the substrate.

According to another example embodiment, the primarily chemically and mechanically polishing the layer may be performed using a slurry having a temperature of about 30° C. to about 80° C.

The primarily chemically and mechanically polishing the layer may be performed using a polishing pad having a temperature of about 30° C. to about 80° C.

The primarily chemically and mechanically polishing the layer may be performed in a chemical mechanical polishing apparatus having a temperature of about 30° C. to about 80° C.

According to still another example embodiment, the secondarily chemically and mechanically polishing the layer may be performed using a slurry having a temperature of about 5° C. to about 25° C.

Alternatively, the secondarily chemically and mechanically polishing the layer may be performed using a polishing pad having a temperature of about 5° C. to about 25° C.

Further, the secondarily chemically and mechanically polishing the layer may be performed in a chemical mechanical polishing apparatus having a temperature of about 5° C. to about 25° C.

In a method of manufacturing a semiconductor device in accordance with another aspect of the present invention, a substrate on which structures are formed is prepared. Silicon oxide is formed on the substrate until the structures are covered to form a silicon oxide layer having stepped portions. A primary chemical mechanical polishing process is performed on the silicon oxide layer using a first slurry at a temperature of about 30° C. to about 80° C. to remove the stepped portions of the silicon oxide layer. A secondary chemical mechanical polishing process is then carried out on the silicon oxide layer without the stepped portions using a slurry at a temperature of about 5° C. to about 25° C. to form a layer pattern having a flat surface.

In one embodiment the silicon oxide layer comprises a high stepped portion that has a first upper face substantially higher than upper faces of the structures, and a low stepped portion that has a second upper face substantially lower than the first upper face of the high stepped portion. In one embodiment the high stepped portion of the silicon oxide layer is placed in a cell region of the substrate on which the structures are formed, and the low stepped portion of the silicon oxide layer is positioned in a peripheral circuit region of the substrate.

In one embodiment, the primarily chemically and mechanically polishing is carried out using a polishing pad having a temperature of about 30° C. to about 80° C. or a chemical mechanical polishing apparatus having a temperature of about 30° C. to about 80° C.

In one embodiment, the first slurry is substantially the same as the second slurry.

According to the present invention, the method of the present invention may use a slurry including ceria. Thus, the loading effect may be sufficiently reduced so that removal time of the stepped portion of the silicon oxide layer may be shortened. Therefore, the time for polishing the silicon oxide layer having the stepped portions using the present method may be no more than about half as long as a conventional CMP process so that the method of the present invention may have an improved throughput. Further, the stepped portions of the silicon oxide layer may be rapidly polished without increase of a pressure so that a chemical mechanical polishing apparatus may not be damaged.

### BRIEF DESCRIPTION OF THE DRAWINGS

The foregoing and other features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIGS. 1 to 3 are cross-sectional views illustrating a method of chemically and mechanically polishing a layer in accordance with example embodiments of the present invention.

FIG. 4 is a graph illustrating polishing speed variations of a silicon oxide layer in accordance with an example embodiment of the present invention.

FIG. 5 is a graph illustrating polishing speed variations of a flat silicon oxide layer relative to temperature variations in accordance with an example embodiment of the present invention.

FIG. 6 is a graph illustrating a removal rate of a silicon oxide layer in accordance with an example embodiment of the present invention.

FIGS. 7 to 10 are cross-sectional views illustrating a method of manufacturing a semiconductor device in accordance with example embodiments of the present invention.

### DESCRIPTION OF THE EMBODIMENTS

The present invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this description will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one ordinarily skilled in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

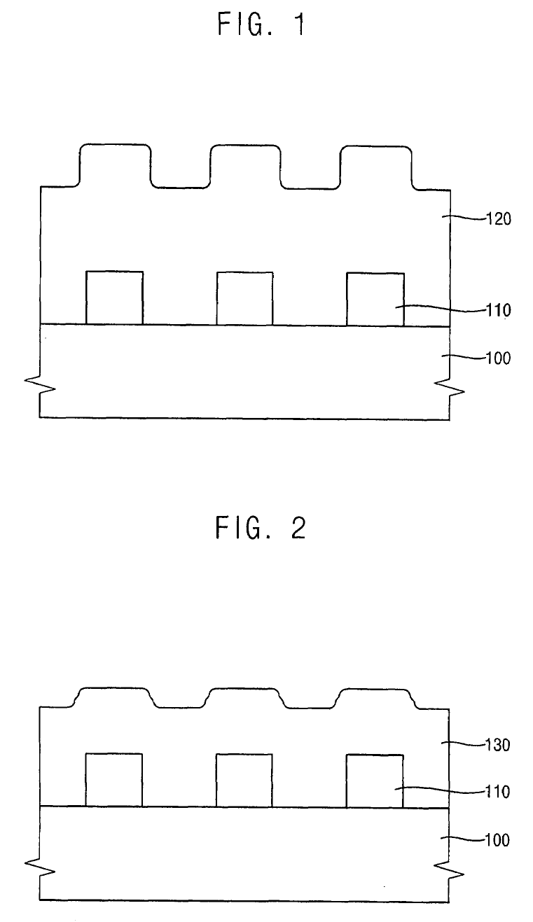

FIGS. 1 to 3 are cross-sectional views illustrating a method of chemically and mechanically polishing a layer in accordance with example embodiments of the present invention.

Referring to FIG. 1, a semiconductor substrate 100 on which a layer 120 having stepped portions is formed is prepared. In an example embodiment, the semiconductor substrate 100 may include a silicon substrate having a cell region and a peripheral circuit region. Additionally, structures 110 such as a hard mask, an electrode, a conductive layer, a conductive layer pattern, an insulation layer, a metal wiring, an insulation layer pattern, etc., may be formed on the semiconductor substrate 100. Further, the structures 110 may be formed in the cell region of the semiconductor substrate 100.

In example embodiments, when the layer 120 includes silicon oxide, a silicon oxide layer is formed by depositing or forming silicon oxide on the structures 110 so that the silicon oxide layer has stepped portions. Alternatively, the layer 120 may have a high stepped portion having a first upper face that is substantially higher than that of the structures 110, and a low stepped portion having a second upper face that is substantially lower than that of the structures 110. Here, the high stepped portion of the layer 120 may be formed in the cell region of the semiconductor substrate 100 on which the structures 110 are positioned. Further, the low stepped portion of the layer 120 may be formed in the peripheral region of the semiconductor substrate 100. Surfaces of the high stepped portion and the low stepped portion in the layer 120 may be non-linear.

As described above, the layer 120 may include the silicon oxide layer including silicon oxide. In example embodiments, the layer 120 may be formed by a plasma enhanced chemical vapor deposition (PECVD) process, a high density plasma-CVD (HDP-CVD) process, a spin coating process, etc. Examples of silicon oxide in the layer 120 may include boro-phosphor silicate glass (BPSG), phosphor silicate glass (PSG), undoped silicate glass (USG), spin on glass (SOG), etc. Further, the layer 120 may have a thickness for sufficiently filling a space between the structures 110 positioned in the cell region of the semiconductor substrate 100. Here, when the stepped portions of the layer 120 may be removed by a conventional chemical mechanical polishing (CMP) process using a slurry under conventional conditions, an excessive polishing time for removing the stepped portions may be required due to a low removal rate of the stepped portions in an initial period of the conventional CMP process. Therefore, according to the method of the present invention, the stepped portions of the layer 120 including silicon oxide may be rapidly removed.

Referring to FIG. 2, a primary CMP process is carried out on the layer 120 to form a flat or flattened layer 130 without the stepped portions. The primarily CMP process may be carried out at a temperature of about 30° C. to about 80° C. to form a flat or flattened layer 130 without the stepped portions.

In example embodiments, a slurry including a ceria abrasive may be supplied to a polishing pad of a CMP apparatus. The slurry may include about 0.5% to about 10% by weight of the ceria abrasive, about 0.1% to about 3.0% by weight of a surfactant, and remaining water.

The layer 120 makes contact with the polishing pad onto which the ceria slurry is supplied to primarily chemically and mechanically polish the stepped portions of the layer 120. Here, the primary CMP process may be carried out under a first process condition, for example, at a temperature of about 30° C. to about 80° C., preferably about 40° C. to about 70° C.

When the layer 120 is primarily chemically and mechanically polished using the slurry at a temperature of about 30° C. to about 80° C., a removal rate of the stepped portions of the layer 120 including silicon oxide may be about 1 to about 2 times faster than that of the conventional CMP process. Therefore, the stepped portions of the silicon oxide layer may be mechanically polished by the ceria slurry at a first speed under a temperature influence of about 30° C., rather than chemically polished. In an example embodiment, the first speed may be about 2,500 Å/min to about 3,200 Å/min.

The primary CMP process may be carried out using the slurry having a temperature of about 30° C. to about 80° C. That is, the first process condition of the primary CMP process may be maintained by the slurry having the temperature of about 30° C. to about 80° C.

Alternatively, the primary CMP process may be carried out using a polishing pad having a temperature of about 30° C. to about 80° C. That is, the first process condition of the primary CMP process may be maintained by the polishing pad having a temperature of about 30° C. to about 80° C.

The primary CMP process may also be carried out in a CMP apparatus having a temperature of about 30° C. to about 80° C. That is, the first process condition of the primary CMP process may be maintained by the CMP apparatus having a temperature of about 30° C. to about 80° C.

Furthermore, the primary CMP process may be carried out using a slurry including ceria, the polishing pad and the CMP apparatus having a temperature of about 30° C. to about 80° C. That is, the first process condition of the primary CMP process may be maintained by the ceria slurry, the polishing pad and the CMP apparatus having a temperature of about 30° C. to about 80° C.

The primary CMP process of example embodiments may solve problems caused when the stepped portions of the layer are polished using the slurry including the ceria abrasive, i.e., a cerium oxide abrasive. Therefore, the slurry used in the primary CMP process of example embodiments may include all of the slurries applied to current semiconductor processes. Thus, the type of slurry may not be specifically restricted herein.

Referring to FIG. 3, a secondary CMP process is carried out on the flat or flattened layer 130 without the stepped portions to form a layer pattern 140 having a flat surface and a desired thickness. The secondary CMP process may be executed at a temperature of about 5° C. to about 25° C. to form a layer pattern 140 having a flat surface and a desired thickness.

In example embodiments, a slurry including ceria abrasive may be supplied to the polishing pad of the CMP apparatus. The flat or flattened layer 130 makes contact with the polishing pad onto which the ceria slurry is supplied to secondarily chemically and mechanically polish a surface of the flat or flattened layer 130. Here, the secondary CMP process for reducing a thickness of the flat or flattened layer 130 may be carried out under a second process condition, for example, at a temperature of about 5° C. to about 25° C. When the flat or flattened layer 130 is secondarily chemically and mechanically polished using the slurry including ceria at a temperature of about 5° C. to about 25° C., the flat or flattened layer 130 may be effectively planarized. That is, a polishing speed may be the most superior in the second process condition.

In example embodiments, the secondary CMP process may be carried out using a ceria slurry composition having a temperature of about 5° C. to about 25° C. That is, the first process condition of the secondary CMP process is maintained by the slurry having the temperature of about 5° C. to about 25° C.

Alternatively, the secondary CMP process may be carried out using a polishing pad having a temperature of about 30° C. to about 80° C. That is, the first process condition of the primary CMP process may be maintained by the polishing pad having the temperature of about 5° C. to about 25° C.

The primary CMP process may also be carried out in a CMP apparatus having a temperature of about 30° C. to about 80° C. That is, the first process condition of the primary CMP process may be maintained by the CMP apparatus having the temperature of about 5° C. to about 25° C.

Furthermore, the primary CMP process may be carried out using a slurry including ceria, the polishing pad and the CMP apparatus having a temperature of about 30° C. to about 80° C. That is, the first process condition of the primary CMP process may be maintained by the slurry, the polishing pad and the CMP apparatus having the temperature of about 5° C. to about 25° C.

In an example embodiment, the secondary CMP process may be carried out until the layer pattern 140 serves as a self-polishing stop layer by distributing a polishing pressure on the layer pattern 140.

When the secondary CMP process is carried out using the slurry, the stepped portions of the layer pattern 140 becomes very low. Thus, a contact area between the polishing pad and the layer pattern 140 may be widened so that the layer pattern 140 may have a self-stopping characteristic.

The self-stopping characteristic may be caused by mechanical hindrance of the abrasive due to the surfactant in the ceria slurry, and by physical fineness of the layer pattern 140 due to absorption of the surfactant on the layer pattern. Further, the self-stopping characteristic may be caused by distributing the polishing pressure applied to the polishing pad along the surface of the polishing stop layer to decrease the polishing pressure applied to the polishing stop layer. As a result, the flat or flattened layer 130 without the stepped portions is converted into the layer pattern 140 having the flat surface.

According to example embodiments of the present invention, the polishing method may be advantageously employed in a semiconductor fabrication process for planarizing an insulation layer having stepped portion that functions as to insulate a gate structure, a wiring structure, a pad structure, a contact, a capacitor, a metal wiring, etc.

Evaluating Polishing Speed Variances of Silicon Oxide Layers in Accordance with Temperatures

To evaluate polishing speed variances of stepped portions on silicon oxide layers in accordance with polishing temperatures in primarily chemically and mechanically polishing the silicon oxide layers using ceria slurry, semiconductor substrates on which the silicon oxide layers having the stepped portions were prepared. The semiconductor substrates on which the silicon oxide layers were formed were chemically and mechanically polished at room temperature, i.e., 17° C. to 20° C. and at a temperature of 50° C. to 80° C., respectively. Here, the ceria slurry included 3% by weight of a ceria abrasive, 0.8% by weight of polyacrylic acid, and remaining water containing a pH adjuster. Further, the ceria slurry had a pH scale of 6. The CMP process was carried out under conditions in following Table 1 using Reflexion manufactured by AMAT Company.

TABLE 1

| | |
|---|---|
| Polishing pressure (psi) | 4.4 (inner tube)/7 (retaining ring)/ |
| | 2 (membrane) |
| Rotational speed of CMP | 78 (head)/86 (platen) |
| apparatus (RPM) | |
| Flux of ceria slurry (ml/min) | 200 |
| Conditioner pressure (psi) | 5.9 |
| Rotational speed of conditioner | 100 |
| (RPM) | |

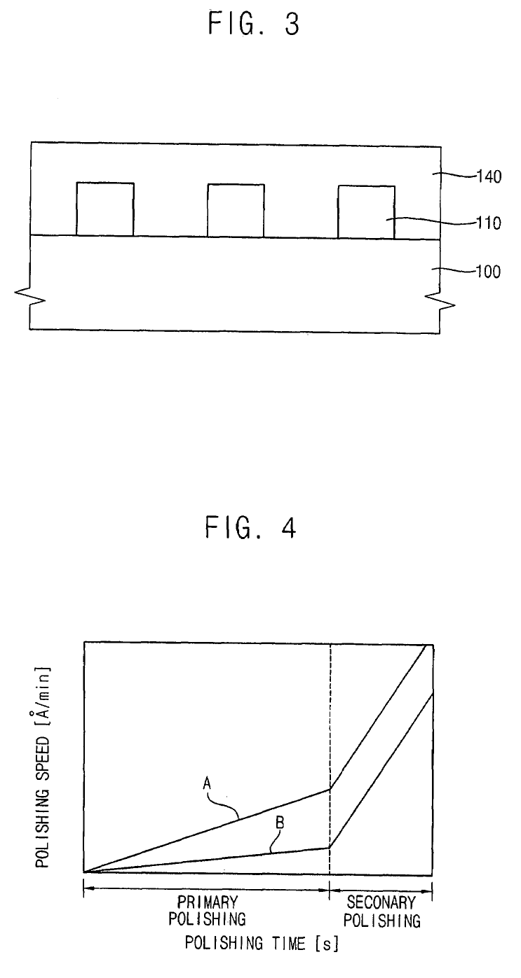

FIG. 4 is a graph illustrating polishing speed variations of a silicon oxide layer in accordance with an example embodiment of the present invention.

Referring to FIG. 4, according to the polishing method of the present invention, the stepped portions of the silicon oxide layer are primarily chemically and mechanically polished at a temperature of 50° C. to 80° C. Thus, as illustrated a line A on the graph, it can be noted that the stepped portions of the silicon oxide layer are rapidly polished in an initial period.

In contrast, according to the conventional CMP process, the stepped portions of the silicon oxide layer are primarily chemically and mechanically polished at room temperature. Thus, as illustrated a line B on the graph, it can be noted that the stepped portions of the silicon oxide layer are very slowly polished in the initial period.

Therefore, when the lines A and B are compared to each other, it can be noted that the time for polishing the stepped portions of the silicon oxide layer using the polishing method of the present invention is no more than about half the time of the conventional CMP method.

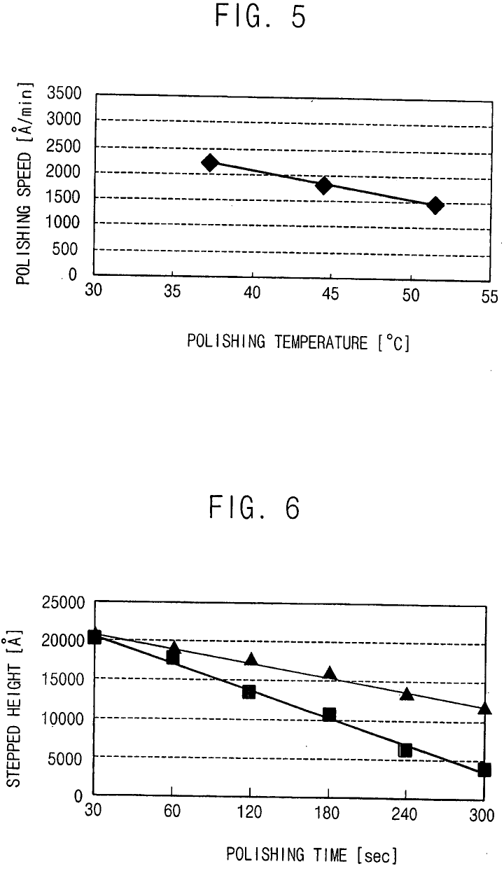

FIG. 5 is a graph illustrating polishing speed variations of a flat silicon oxide layer relative to temperature variations in accordance with an example embodiment of the present invention.

Referring to FIG. 5, when the silicon oxide layer having the stepped portions is chemically and mechanically polished using the slurry including ceria, it may be noted that a polishing speed of the silicon oxide layer becomes gradually reduced in proportion to the increase in polishing temperature. For example, the polishing speed of the silicon oxide layer is about 2,200 Å/min at a temperature of about 36° C. Further, the polishing speed of the silicon oxide layer is about 1,800 Å/min at a temperature of about 45° C. Therefore, it can be noted that the polishing speed is proportional to the increase of the polishing temperature during the flat silicon oxide layer is chemically and mechanically polished.

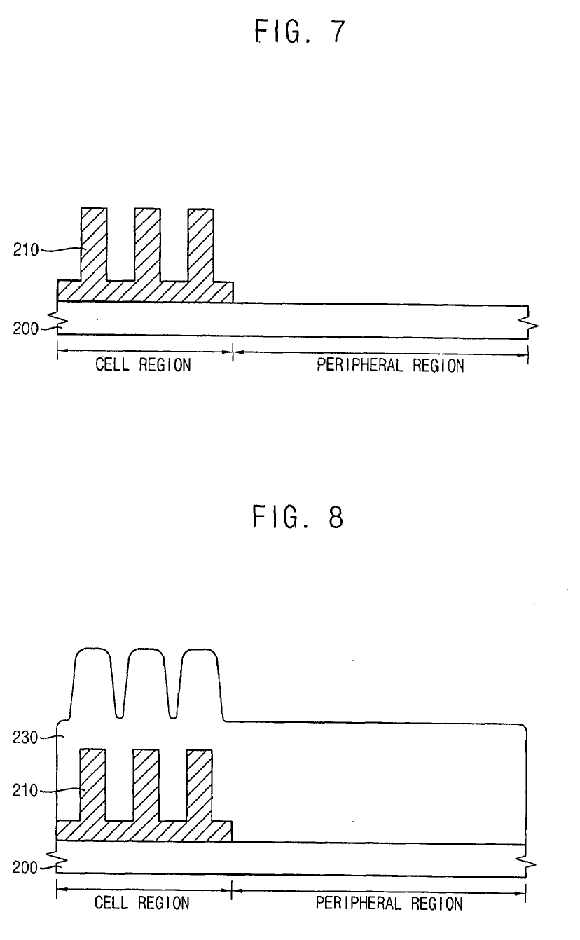

FIG. 6 is a graph illustrating a removal rate of a silicon oxide layer in accordance with an example embodiment of the present invention.

Referring to FIG. 6, when the silicon oxide layer having a step of about 2,000 Å is chemically and mechanically polished using the ceria slurry, it can be noted that the stepped portions of the silicon oxide layer are removed proportionally to the increase in polishing time. For example, as illustrated by the upper line marked by triangles on the graph, when the silicon oxide layer is primarily chemically and mechanically polished at a temperature of about 60° C. for a time of about 300 seconds, a removed thickness of the stepped portions of the silicon oxide layer is about 16,000 Å. Further, as illustrated by the lower line marked by squares on the graph, when the silicon oxide layer is primarily chemically and mechanically polished at a temperature of about 18° C. for a time of about 300 seconds, a removed thickness of the stepped portions of the silicon oxide layer is about 8,500 Å. Thus, it may be noted that the removal rate of the stepped portions is proportional to the increase of the polishing temperature. As a result, the loading effect of the CMP process may be suppressed in the initial period for removing the stepped portions so that the CMP process may be completed in a short time.

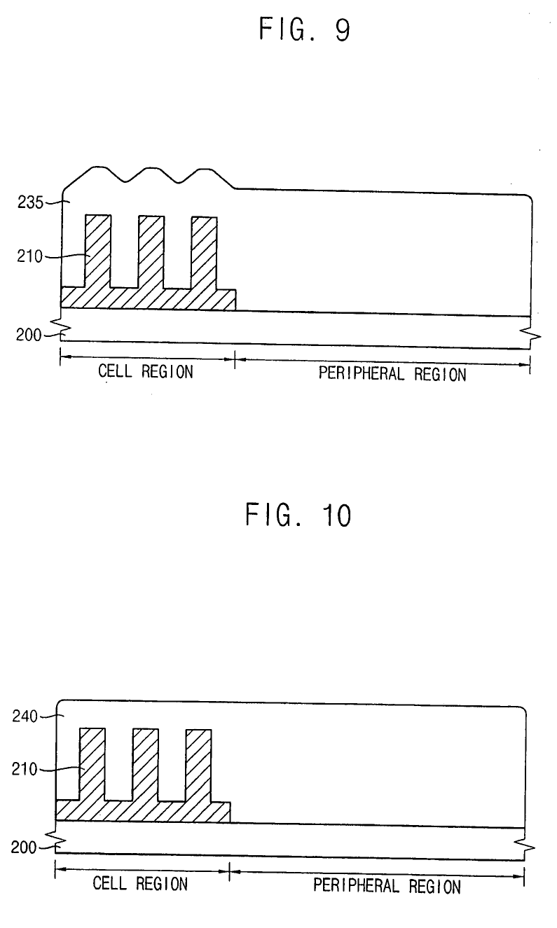

FIGS. 7 to 10 are cross-sectional views illustrating a method of manufacturing a semiconductor device in accordance with example embodiments of the present invention.

Referring to FIG. 7, a semiconductor substrate 200 on which structures 210 are formed is prepared.

In example embodiments, the semiconductor substrate 200 may include a silicon substrate having a cell region and a peripheral circuit region. The structures 210 having high heights are formed in the cell region of the semiconductor substrate 200. The structures 210 may include a transistor having a gate, a bit line electrically connected to a first contact region of the transistor, a capacitor electrically connected to a second contact region of the transistor, etc. The capacitor may have a cylindrical shape. Further, the capacitor may include a lower electrode, a dielectric layer and an upper electrode. The capacitor may be electrically connected to an upper metal wiring. Therefore, the structures 210 having stepped portions that are higher than the peripheral circuit region are formed in the cell region of the semiconductor substrate 200.

Referring to FIG. 8, silicon oxide is deposited on the semiconductor substrate 200 having the structures 210 to form a silicon oxide layer 220 having stepped portions, which are formed by the structures 210. The silicon oxide layer 220 covers the structures 210. Further, the silicon oxide layer 220 functions as to insulate the structures 210 from a conductive wiring (not illustrated) formed later.

The silicon oxide layer 220 has a high stepped portion and a low stepped portion owing to the structures 210. In this example embodiment, the high stepped portion of the silicon oxide layer 220 is positioned in the cell region of the semiconductor substrate 200 in which the structures 210 are formed. Further, the low stepped portion is located in the peripheral region of the semiconductor substrate 200. Particularly, the high stepped portion of the silicon oxide layer 220 in the cell region of the semiconductor substrate 200 has a high surface step due to a space between the structures 210. In contrast, the low stepped portion of the silicon oxide layer 220 in the peripheral region of the semiconductor substrate 200 has a low surface step because the structures 210 are not placed in the peripheral region.

Referring to FIG. 9, a primary CMP process is carried out on the silicon oxide layer 220 at a temperature of about 30° C. to about 80° C. to form a preliminary silicon oxide layer 230. Here, the preliminary silicon oxide layer 230 may not have stepped portions of the high stepped portion.

In this example embodiment, ceria slurry including a ceria abrasive is supplied to a polishing pad of a CMP apparatus. The stepped portions of the silicon oxide layer 220 makes contact with the polishing pad onto which the ceria slurry is supplied to primarily chemically and mechanically polish the stepped portions of the silicon oxide layer 220. Here, the primary CMP process may be carried out under a first process condition, for example, at a temperature of about 30° C. to about 80° C., preferably about 40° C. to about 70° C. Here, when the silicon oxide layer 220 is primarily chemically and mechanically polished using the ceria slurry at a temperature of about 30° C. to about 80° C., a removal rate of the stepped portions of the silicon oxide layer 220 may be about 1 time to about 2 times faster than that of the conventional CMP process. Therefore, the stepped portions of the silicon oxide layer may be mechanically polished by the ceria slurry at a first speed under a temperature influence of about 30° C., rather than chemically polished.

The primary CMP process may be carried out using a slurry having a temperature of about 30° C. to about 80° C. That is, the first process condition of the primary CMP process is maintained by the slurry having the temperature of about 30° C. to about 80° C.

Alternatively, the primary CMP process may be carried out using a polishing pad having a temperature of about 30° C. to about 80° C. That is, the first process condition of the primary CMP process may be maintained by the polishing pad having the temperature of about 30° C. to about 80° C.

Further, the primary CMP process may be carried out in a CMP apparatus having a temperature of about 30° C. to about 80° C. That is, the first process condition of the primary CMP process may be maintained by the CMP apparatus having the temperature of about 30° C. to about 80° C.

Furthermore, the primary CMP process may be carried out using a ceria slurry composition, the polishing pad and the CMP apparatus having a temperature of about 30° C. to about 80° C. That is, the first process condition of the primary CMP process may be maintained by the ceria slurry, the polishing pad and the CMP apparatus having the temperature of about 30° C. to about 80° C.

The primary CMP process of example embodiments may solve problems caused when the stepped portions of the layer are polished using the slurry including the ceria abrasive, i.e., a cerium oxide abrasive. Therefore, the slurry including ceria used in the primary CMP process of this example embodiment may include all of ceria slurries applied to current semiconductor processes. Thus, the type of the slurry may not be specifically restricted herein.

Referring to FIG. 10, a secondary CMP process is carried out on the preliminary silicon oxide layer 230 at a temperature of about 5° C. to about 25° C. to form a silicon oxide layer pattern 240 having a flat surface and a desired thickness.

In example embodiments, a slurry including ceria abrasive may be supplied to the polishing pad of the CMP apparatus. The preliminary silicon oxide layer 230 makes contact with the polishing pad onto which the ceria slurry is supplied to secondarily chemically and mechanically polish a surface of the preliminary silicon oxide layer 230. Here, the secondary CMP process for reducing a thickness of the preliminary silicon oxide layer 230 may be carried out under a second process condition, for example, at a temperature of about 5° C. to about 25° C. Here, when the preliminary silicon oxide layer 230 is secondarily chemically and mechanically polished using the ceria slurry at a temperature of about 5° C. to about 25° C., the preliminary silicon oxide layer 230 may be effectively planarized. That is, a polishing speed may be the most superior in the second process condition.

The secondary CMP process may be carried out using a slurry having a temperature of about 5° C. to about 25° C. That is, the first process condition of the secondary CMP process is maintained by the slurry having the temperature of about 5° C. to about 25° C.

Alternatively, the secondary CMP process may be carried out using a polishing pad having a temperature of about 30° C. to about 80° C. That is, the first process condition of the primary CMP process may be maintained by the polishing pad having the temperature of about 5° C. to about 25° C.

Further, the primary CMP process may be carried out in a CMP apparatus having a temperature of about 30° C. to about 80° C. That is, the first process condition of the primary CMP process may be maintained by the CMP apparatus having the temperature of about 5° C. to about 25° C.

Furthermore, the primary CMP process may be carried out using a ceria slurry composition, the polishing pad and the CMP apparatus having a temperature of about 30° C. to about 80° C. That is, the first process condition of the primary CMP process may be maintained by the slurry, the polishing pad and the CMP apparatus having the temperature of about 5° C. to about 25° C.

According to the present invention, the polishing method may sufficiently suppress the loading effect using the ceria slurry so that removal time of the stepped portion of the silicon oxide layer may be shortened. Therefore, the time for polishing the silicon oxide layer having the stepped portions using the present method may be no more than about half that of a conventional CMP process so that the polishing method may have an improved throughput. Further, the stepped portions of the silicon oxide layer may be rapidly polished without an increase in pressure so that the chemical mechanical polishing apparatus may not be damaged. As a result, the twice control type method of chemically and mechanically polishing the layer having the high planarity may be widely applied to a semiconductor fabrication processes.

The foregoing is illustrative of the present invention and is not to be construed as limiting thereof. Although a few example embodiments of the present invention have been described, those skilled in the art will readily appreciate that many modifications are possible in the example embodiments without materially departing from the novel teachings and advantages of this invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A method of polishing a layer having high planarity, comprising:
preparing a substrate on which the layer having stepped portions is formed;
primarily chemically and mechanically polishing the layer at a temperature of about 30° C. to about 80° C. to remove the stepped portions of the layer; and
secondarily chemically and mechanically polishing the layer without the stepped portions at a temperature of about 5° C. to about 25° C. to form a layer pattern having a desired thickness.

2. The method of claim 1, wherein the layer comprises a silicon oxide layer, and the silicon oxide layer has the stepped portions by formation of the silicon oxide layer on structures that are formed on the substrate.

3. The method of claim 1, wherein the primarily and the secondarily chemically and mechanically polishing are carried out using about 0.5% to about 10% by weight of a cerium oxide abrasive, about 0.1% to about 3.0% by weight of a surfactant, and remaining water.

4. The method of claim 1, wherein the primarily chemically and mechanically polishing is carried out using a slurry having a temperature of about 30° C. to about 80° C.

5. The method of claim 1, wherein the primarily chemically and mechanically polishing is carried out using a polishing pad having a temperature of about 30° C. to about 80° C.

6. The method of claim 1, wherein the primarily chemically and mechanically polishing is carried out in a chemical mechanical polishing apparatus having a temperature of about 30° C. to about 80° C.

7. The method of claim 1, wherein the secondarily chemically and mechanically polishing is carried out using a slurry having a temperature of about 5(C to about 25° C.

8. The method of claim 1, wherein the secondarily chemically and mechanically polishing is carried out using a polishing pad having a temperature of about 5° C. to about 25° C.

9. The method of claim 1, wherein the secondarily chemically and mechanically polishing is carried out in a chemical mechanical polishing apparatus having a temperature of about 5° C. to about 25° C.

10. A method of manufacturing a semiconductor device, comprising:
preparing a substrate on which structures are formed;
forming a silicon oxide layer on the substrate to cover the structures, the silicon oxide layer having stepped portions;
primarily chemically and mechanically polishing the silicon oxide layer using a first slurry at a temperature of about 30° C. to about 80° C. to remove the stepped portions of the silicon oxide layer; and
secondarily chemically and mechanically polishing the silicon oxide layer without the stepped portions using a second slurry at a temperature of about 5° C. to about 25° C. to form a layer pattern having a flat surface.

11. The method of claim 10, wherein the silicon oxide layer comprises a high stepped portion that has a first upper face substantially higher than upper faces of the structures, and a low stepped portion that has a second upper face substantially lower than the first upper face of the high stepped portion.

12. The method of claim 11, wherein the high stepped portion of the silicon oxide layer is placed in a cell region of the substrate on which the structures are formed, and the low stepped portion of the silicon oxide layer is positioned in a peripheral circuit region of the substrate.

13. The method of claim 10, wherein the primarily chemically and mechanically polishing is carried out using a polishing pad having a temperature of about 30° C. to about 80° C. or a chemical mechanical polishing apparatus having a temperature of about 30° C. to about 80° C.

14. The method of claim 10, wherein the first slurry is substantially the same as the second slurry.
